(19) United States
(12) Patent Application Publication
(10) Pub. No.: US 2023/0240001 A1
(43) Pub. Date: Jul. 27, 2023

(54) Wiring Board and Signal Connecting Structure

(71) Applicant: Nippon Telegraph and Telephone Corporation, Tokyo (JP)

(72) Inventors: Hitoshi Wakita, Tokyo (JP); Norio Sato, Tokyo (JP)

(21) Appl. No.: 18/002,605

(22) PCT Filed: Jul. 2, 2020
(86) PCT No.: PCT/JP2020/026030

§ 371 Date: Dec. 20, 2022

(51) Int. Cl. H05K 1/02; H05K 1/11

(52) U.S. Cl. CPC H05K 1/0245; H05K 1/115; H05K 1/0222; H05K 2201/093

(57) ABSTRACT

A wiring substrate is a wiring substrate including a plurality of differential pairs. Each of the differential pairs includes a first signal conductor, a first connection portion connected to the first signal conductor via a first via, a second signal conductor, and a second connection portion connected to the second signal conductor via a second via. The first signal conductor and the second signal conductor are arranged on different planes parallel to a bottom surface of the wiring substrate and overlap in a vertical direction. The first connection portion and the second connection portion are arranged on a top surface of the wiring substrate at a predetermined interval in a signal transmission direction. Adjacent differential pairs among the plurality of differential pairs are arranged at a predetermined interval in the signal transmission direction and at a predetermined interval in a direction perpendicular to the signal transmission direction.

### CROSS-REFERENCE TO RELATED APPLICATIONS

This patent application is a national phase filing under section 371 of PCT application no. PCT/JP2020/026030, filed on Jul. 2, 2020, which is incorporated herein by reference in its entirety.

### TECHNICAL FIELD

The present disclosure relates to a wiring substrate and a signal connection structure for transmitting a differential signal.

### BACKGROUND

In recent years, the amount of data transmitted over networks has been steadily increasing. In response to this increase, methods for improving the transmission speed of data have been researched and developed. Differential signal transmission with high resistance against in-phase noise is useful for transmission and reception of data at high speed, and thus, is widely employed in high-speed electronic devices such as integrated circuits (ICs) and package substrates including ICs.

In differential signaling, pieces of data ideally having a phase difference of 180 degrees or having opposite signs, i.e., positive and negative signs, are transmitted by using two signal paths. This allows pieces of in-phase noise to cancel each other, and when a plurality of signals are transmitted using differential signaling, signals having a positive phase and signals having a negative phase are strongly coupled, and thus, a configuration having high resistance against crosstalk is obtained.

For example, for optical transceivers, polarization multiplexing and wavelength multiplexing are used, and multi-valuing technologies are also used in recent years. Differential signaling is utilized for input and output of data in these technologies and the number of channels for the data increases when the data is more multiplexed.

Furthermore, differential signaling is widely utilized not only for transmission of data in optical applications, but also for transmission of data in electric applications. The above-mentioned data is transmitted from an active element such as an application specific integrated circuit (ASIC) to a package substrate for enclosing the element and a board for connecting package substrates. Here, a top surface of the package substrate functions as a chip mounting surface. A signal generated from the chip is transmitted from the top surface of the package to a rear surface of the package. The rear surface of the package has a structure capable of transmitting the signal to a pattern for connection with the board such as a ball grid array or a land grid array.

The ball grid array, the land grid array, or the like is connected to the board for mounting the package substrate by solder balls, solder, or the like. The layout of this ball grid array is defined by a predetermined standard. In recent years, the diameter of the solder balls is about 0.1 mmφ and the pitch interval of the solder balls is about 0.3 mm, and thus, components can be arranged at high density. Furthermore, it is possible to provide signal input and output portions not only on the four sides of the package substrate, but also inside the package substrate, and thus, the present technology is widely used in ASIC packages having a large number of input and output portions.

For example, NPLs 1, 2, and 3 disclose structures and design methods of RF via differential wiring structures in multilayer wiring substrates.

FIG. 7 illustrates a connection structure including a ball grid array and differential wiring disclosed in NPLs 1 and 2. A chip 1502 is mounted above a board 1501. In differential transmission, two signals, which are a positive signal and a negative signal, are coupled to be transmitted. Consequently, at least two wirings (for example, 1511 and 1512 in the drawing) and two connection portions (for example, 1521 and 1522 in the drawing) are required for one signal. In the connection structures disclosed in NPLs 1 and 2, at least two connection portions (for example, 1521 and 1522 in the drawing) are arranged perpendicular to a signal transmission direction (x-direction in the drawing) on the board 1501, and thus, high connectivity with a wiring on the board 1501 is obtained.

Furthermore, FIG. 8 illustrates a connection structure disclosed in NPL 3. A chip 1602 is mounted above a board 1601. FIG. 8 illustrates a differential pair including a signal path of a wiring 1611 and a connection portion 1621 and a signal path of a wiring 1612 and a connection portion 1622, and a differential pair including a signal path of a wiring 1613 and a connection portion 1623 and a signal path of a wiring 1614 and a connection portion 1624. In this connection structure, the resistance against crosstalk can be increased by a configuration in which, with respect to the signal transmission direction, connection portions of a differential wiring pair (for example, 1621 and 1622) are arranged parallel to the signal transmission direction and two adjacent differential wiring pairs are arranged with an offset to each another.

### CITATION LIST

### Non Patent Literature

NPL 1: “De-Mystifying the 28 Gb/s PCB Channel: Design to Measurement” Heidi Barnes. DesignCon2014 13-FR3 presentation. https://www.keysight.com/upload/cmc_upload/All/13_FR3Combined_DeMystifyingthe28gbs PCBChannel.pdf.

NPL 2: “Parallel Optical Interconnect between Ceramic BGA Packages on FR4 Board using Embedded Waveguides and Passive Optical Alignments”. Mikko Karppinen., et al. Proceedings of ECTC 2006.

NPL 3: “Design of Package BGA Pin-out for >25 Gb/s High Speed SerDes Considering PCB Via Crosstalk”. Wei Yao. et al., Proceedings of 2015 IEEE Symposium on Electromagnetic Compatibility and Signal Integrity.

### SUMMARY

### Technical Problem

However, in the connection structure disclosed in NPLs 1 and 2, when a plurality of differential channels are provided, the pitch between the connection portions of the plurality of differential channels is set to a predetermined pitch, and thus, unfortunately, an arrangement area of the connection portions increases.

Furthermore, adjacent channels exist on the same surface as the signal wiring, and thus, unfortunately, crosstalk between channels also increases.

In the connection structure disclosed in NPL 3, the differential wiring includes coupled microstrip lines. In order to arrange two differential wirings, it is necessary to widen the interval (pitch) of the solder balls and the interval (pitch) of the connection portions on the board, and thus, unfortunately, the connection structure cannot be applied to boards in which components are arranged at high density.

### Means for Solving the Problem

In order to solve the problems described above, a wiring substrate according to embodiments of the present disclosure is a wiring substrate including a plurality of differential pairs, in which each of the plurality of differential pairs includes a first signal conductor, a first connection portion connected to the first signal conductor via a first via, a second signal conductor, and a second connection portion connected to the second signal conductor via a second via, the first signal conductor and the second signal conductor are arranged on different planes parallel to a bottom surface of the wiring substrate and overlap in a vertical direction, the first connection portion and the second connection portion are arranged on a top surface of the wiring substrate at a predetermined interval in a signal transmission direction, and adjacent differential pairs among the plurality of differential pairs are arranged at a predetermined interval in the signal transmission direction and at a predetermined interval in a direction perpendicular to the signal transmission direction.

### Effects of Embodiments of the Invention

According to embodiments of the present disclosure, wiring for transmitting a differential signal can be arranged at high density, and a wiring substrate and a signal connection structure having high resistance against crosstalk can be provided.

### BRIEF DESCRIPTION OF THE DRAWINGS

FIG. 1A is a top view of a signal connection structure according to a first embodiment of the present disclosure.

FIG. 1B is a cross-sectional view taken along line IB-IB′ in the top view of the signal connection structure according to the first embodiment of the present disclosure.

FIG. 1C is a cross-sectional view taken along line IC-IC′ in the top view of the signal connection structure according to the first embodiment of the present disclosure.

FIG. 2A is a top view of a signal connection structure according to a second embodiment of the present disclosure.

FIG. 2B is a cross-sectional view taken along line IIB-IIB′ in the top view of the signal connection structure according to the second embodiment of the present disclosure.

FIG. 2C is a cross-sectional view taken along line IIC-IIC′ in the top view of the signal connection structure according to the second embodiment of the present disclosure.

FIG. 3A is a top view of a signal connection structure according to a third embodiment of the present disclosure.

FIG. 3B is a cross-sectional view taken along line IIIB-IIIB′ in the top view of the signal connection structure according to the third embodiment of the present disclosure.

FIG. 3C is a cross-sectional view taken along line IIIC-IIIC′ in the top view of the signal connection structure according to the third embodiment of the present disclosure.

FIG. 4A is a top view of a signal connection structure according to a fourth embodiment of the present disclosure.

FIG. 4B is a cross-sectional view taken along line IVB-IVB′ in the top view of the signal connection structure according to the fourth embodiment of the present disclosure.

FIG. 4C is a cross-sectional view taken along line IVC-IVC′ in the top view of the signal connection structure according to the fourth embodiment of the present disclosure.

FIG. 5A is a top view of a signal connection structure according to a fifth embodiment of the present disclosure.

FIG. 5B is a cross-sectional view taken along line VB-VB′ in the top view of the signal connection structure according to the fifth embodiment of the present disclosure.

FIG. 6A is a top view of a signal connection structure according to a sixth embodiment of the present disclosure.

FIG. 6B is a cross-sectional view taken along line VIB-VIB′ in the top view of the signal connection structure according to the sixth embodiment of the present disclosure.

FIG. 7 is a top view of a signal connection structure of the related art.

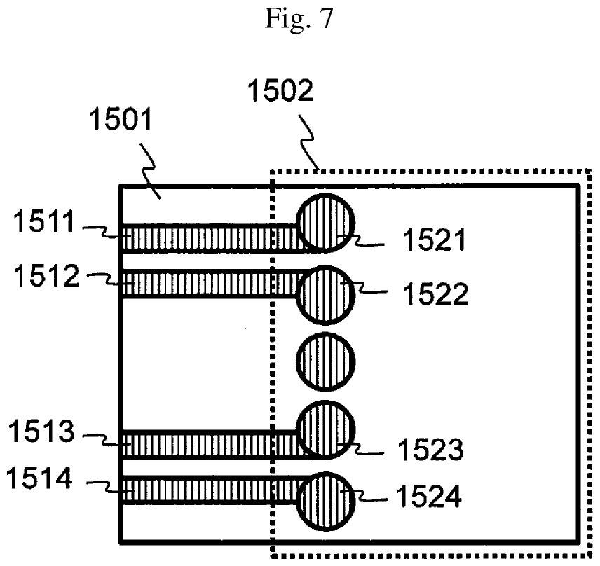

FIG. 8 is a top view of a signal connection structure of the related art.

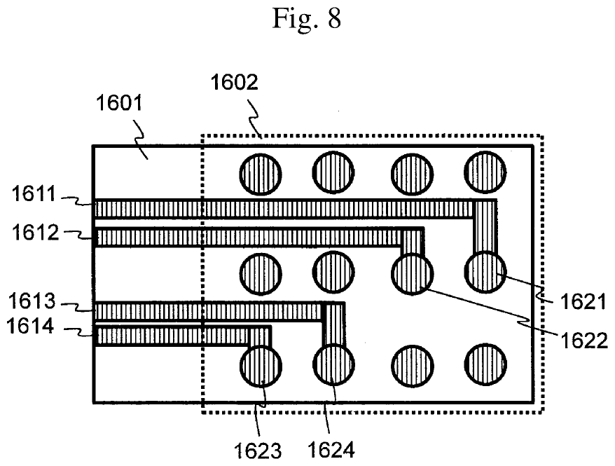

### DETAILED DESCRIPTION OF ILLUSTRATIVE EMBODIMENTS

### First Embodiment

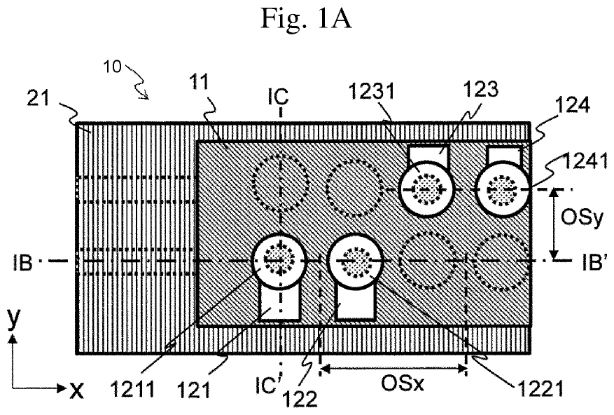

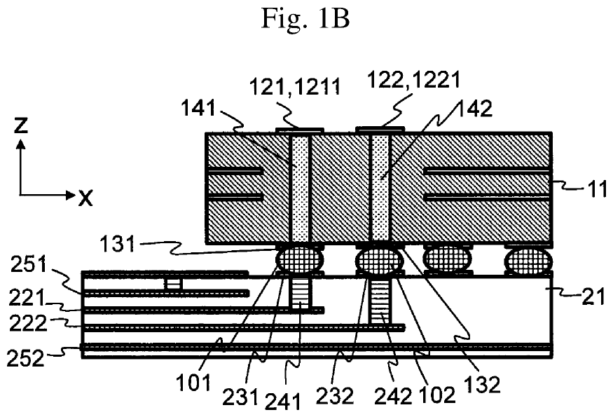

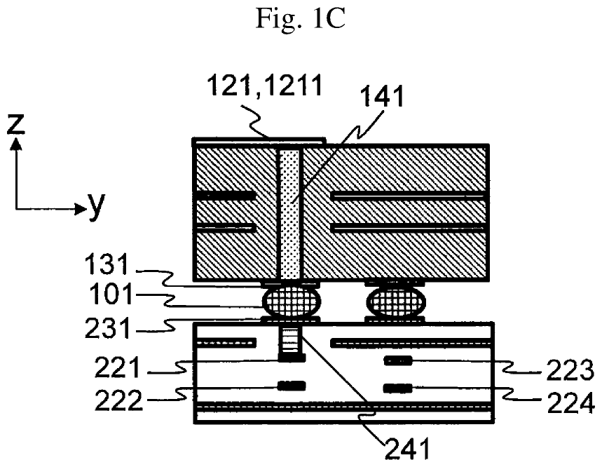

A first embodiment of the present disclosure will be described with reference to FIGS. 1A to 1C.

### Configuration of Signal Connection Structure

FIGS. 1A, 1B, and 1C are a top view of a signal connection structure according to the present embodiment, a cross-sectional view taken along line IB-IB′ in the top view, and a cross-sectional view taken along line IC-IC′ in the top view, respectively.

A signal connection structure 10 includes a package substrate (hereinafter referred to as “dielectric substrate”) ii above a board (hereinafter referred to as “wiring substrate”) 21. Here, the material of the dielectric substrate 11 includes ceramic substrate materials such as low temperature co-fired ceramics (LTCC) and high temperature co-fired ceramics (HTCC), and resin substrate materials such as a build-up substrate.

The dielectric substrate 11 includes signal conductors 121 to 124 and connection portions 1211 to 1241 on a top surface, connection portions 131 to 134 on a bottom surface, and vias 141 to 144. The vias 141 to 144 penetrate the dielectric substrate 11 and connect the signal conductors 121 to 124 and the connection portions 131 to 134.

The wiring substrate 21 includes signal conductors 221 to 224 therein, connection portions 231 to 234 on a top surface, and vias 241 to 244. The vias 241 to 244 connect the signal conductors 221 to 224 and the connection portions 231 to 234.

The connection portions 131 to 134 of the dielectric substrate 11 and the connection portions 231 to 234 of the wiring substrate 21 are electrically connected via conductors 101 to 104. Conductor materials such as solder, solder balls, and conductive paste can be used for the conductors 101 to 104.

Here, the connection portions 1211 to 1241, the connection portions 131 to 134, and the connection portions 231 to 234 are arranged at a predetermined pitch (interval), and the conductors 101 to 104 are also arranged at a similar pitch (interval). For example, the connection portions 1211 and 1221 are arranged in a row in a signal transmission direction (x-direction in the drawings) at an interval of 0.5 mm. The connection portions 1231 and 1241 are also arranged similarly.

The signal conductor 221 and the signal conductor 222 are wired on different planes parallel to the bottom surface of the wiring substrate 21 (x-y plane in FIG. 1).

Furthermore, the signal conductor 221 and the signal conductor 222 are wired so as to overlap each other when viewed from above, in other words, in a vertical direction (z-direction in the drawings). Thus, the signal conductor 221 and the signal conductor 222 form a broadside strip wiring structure.

Similarly, the signal conductor 223 and the signal conductor 224 are wired so as to form a broadside strip wiring structure.

According to such a configuration, a positive phase signal input from the signal conductor 121 on the top surface of the dielectric substrate 11 passes through the connection portion 1211, the via 141, the connection portion 131, the conductor 101, the connection portion 231, and the via 241 in this order, and is conveyed to the signal conductor 221 of the wiring substrate 21.

On the other hand, a negative phase signal input from the signal conductor 122 on the top surface of the dielectric substrate 11 passes through the connection portion 1221, the via 142, the connection portion 132, the conductor 102, the connection portion 232, and the via 242 in this order, and is conveyed to the signal conductor 222 of the wiring substrate 21.

As described above, in the dielectric substrate 11 and the wiring substrate 21, a differential wiring structure is formed by a signal path including the signal conductor 221 and a signal path including the signal conductor 222, and thus, a differential pair a is formed.

Similarly, in the dielectric substrate 11 and the wiring substrate 21, a differential wiring structure is formed by a signal path including the signal conductor 223 and a signal path including the signal conductor 224, and thus, a differential pair b is formed.

Here, the vias and connection portions in each of the differential pairs a and b are arranged in a row on a line parallel with the direction in which the signal is conveyed by the signal conductors 221 and 222 (transmission direction of the differential wiring, which is the x-direction in the drawings). For example, the differential pair b is arranged at an interval of 1 mm (interval of the centers of the differential pairs in the x-direction, which is OSx in the drawing) relative to the differential pair a in the signal transmission direction (x-direction in the drawings).

Furthermore, the differential pair a and the differential pair b are arranged in parallel, but are arranged with an offset at a predetermined interval so as not to be located on the same line. For example, the differential pair b is arranged at an interval of 1 mm (interval of the centers of the differential pairs in the y-direction, which is OSy in the drawing) relative to the differential pair a in a direction perpendicular to the signal transmission direction (y-direction in the drawings).

Consequently, adjacent differential pairs are arranged at a predetermined interval in the signal transmission direction and at a predetermined interval in the direction perpendicular to the signal transmission direction.

According to such a configuration, connection portions can be arranged at high density in the signal transmission direction. That is, the wiring can be arranged at high density.

In addition, by forming the broadside strip wiring structure, the positive and negative signal conductors forming a pair are arranged one above the other in the wiring substrate, and thus a mode is achieved where electromagnetic fields are strongly coupled in an up-down direction in the wiring substrate. As a result, crosstalk between adjacent channels in signal conductor portions can also be suppressed to a low level.

Furthermore, differential channels are formed in a direction of the layers of the wiring substrate (z-direction in the drawings), and thus, the layout for wiring for differential signals in the wiring substrate can be made smaller.

When positive and negative differential signals are input to and conveyed in the signal connection structure 10, excellent high-frequency characteristics are obtained as a result.

Furthermore, the wiring substrate may be a multilayer substrate, and may include, in addition to the signal conductors, layers functioning as ground conductors 411 and 412 and the like in upper and lower layers of the signal conductors.

It is also possible to provide an interlayer via for connecting ground conductors 251 and 252 and the like. Alternatively, it may be possible to provide a penetrating via for connecting ground conductors arranged, in addition to the signal conductors, on the top surface or the bottom surface of the wiring substrate 21. According to such a configuration, it is possible to cover surroundings of the signal conductors with a ground layer and surround the differential channels with vias connecting to the ground, and thus, crosstalk can be suppressed to an even lower level.

As described above, with the signal connection structure according to the present embodiment, it is possible to arrange a plurality of differential pairs at high density and obtain high resistance against crosstalk.

### Second Embodiment

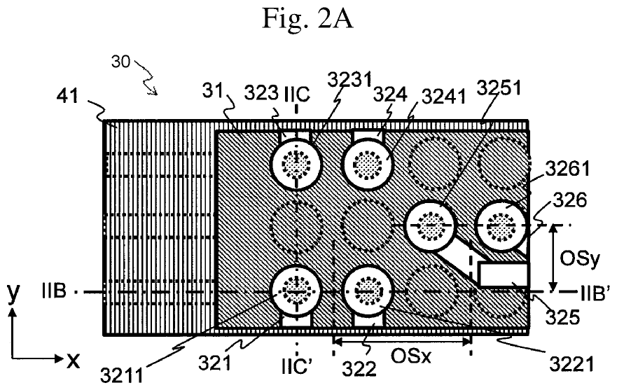

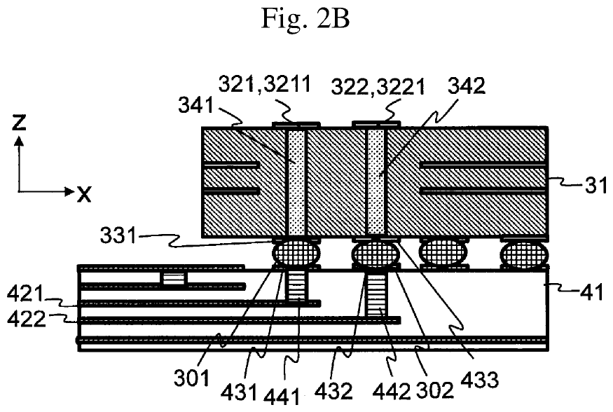

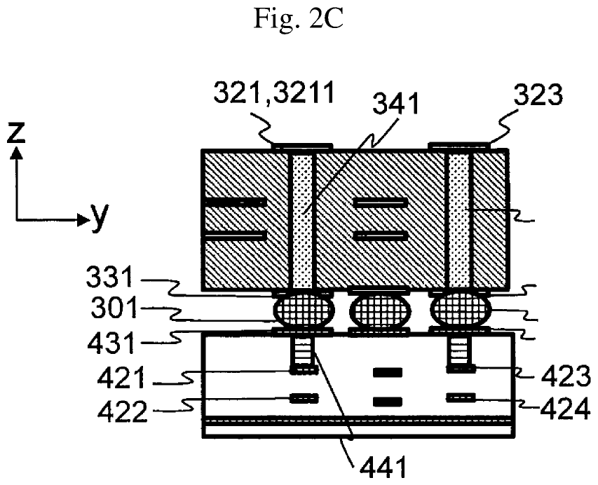

Next, a signal connection structure according to a second embodiment of the present disclosure will be described with reference to FIGS. 2A to 2C. A signal connection structure 30 according to the present embodiment has substantially the same configuration as the signal connection structure 10 according to the first embodiment, and achieves a similar effect. The signal connection structure 30 differs from the signal connection structure 10 in that the signal connection structure 30 includes a plurality of differential pairs.

### Configuration of Signal Connection Structure

FIGS. 2A, 2B, and 2C are a top view of the signal connection structure 30 according to the present embodiment, a cross-sectional view taken along line IIB-IIB′ in the top view, and a cross-sectional view taken along line IIC-IIC′ in the top view, respectively.

The signal connection structure 30 includes a differential pair a including a signal path from a signal conductor 321 to a signal conductor 421 and a signal path from a signal conductor 322 to a signal conductor 422, a differential pair b including a signal path from a signal conductor 323 to a signal conductor 423 and a signal path (not illustrated) from a signal conductor 324 to a signal conductor 424, and a differential pair c including a signal path from a signal conductor 325 to a signal conductor 425 and a signal path (not illustrated) from a signal conductor 326 to a signal conductor 426.

A connection portion 3211 of the signal conductor 321 and a connection portion 3221 of the signal conductor 322 in the differential pair are arranged at an interval of 0.5 mm in a row in the signal transmission direction (x-direction in the drawings). The same applies to connection portions 3231 and 3241 of the signal conductor 323 and the signal conductor 324, and connection portions 3251 and 3261 of the signal conductor 325 and the signal conductor 326.

Each of the differential pairs is arranged on a different straight line parallel to the signal transmission direction (x-direction in the drawings). The differential pair c is arranged at an interval of 1 mm (interval of the centers of the differential pairs in the x-direction, which is OSx in the drawing) in the signal transmission direction (x-direction in the drawings) and at an interval of 1 mm (interval of the centers of the differential pairs in the y-direction, which is OSy in the drawing) in the direction perpendicular to the signal transmission direction (y-direction in the drawings) relative to the differential pair a.

Furthermore, the differential pair b is arranged at an interval of 1 mm (interval of the centers of the differential pairs in the x-direction) in the signal transmission direction (x-direction in the drawings) and at an interval of 1 mm (interval of the centers of the differential pairs in the y-direction) in the direction perpendicular to the signal transmission direction (y-direction in the drawings) relative to the differential pair c.

Consequently, adjacent differential pairs among the plurality of differential pairs are arranged at a predetermined interval in the signal transmission direction and at a predetermined interval in the direction perpendicular to the signal transmission direction.

As a result, the differential pair b is arranged on the same line at an interval of 2 mm (interval of the centers of the differential pairs in the x-direction) relative to the differential pair a in the direction perpendicular to the signal transmission direction (y-direction in the drawings).

As described above, when the differential pairs are arranged alternately at a predetermined interval (offset), wiring can be performed efficiently and crosstalk between adjacent differential pairs can be suppressed.

Thus, with the signal connection structure according to the present embodiment, it is possible to arrange a plurality of differential pairs at a higher density and obtain high resistance against crosstalk.

### Third Embodiment

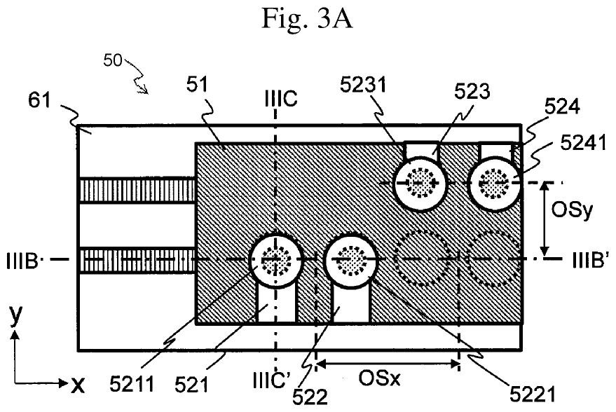

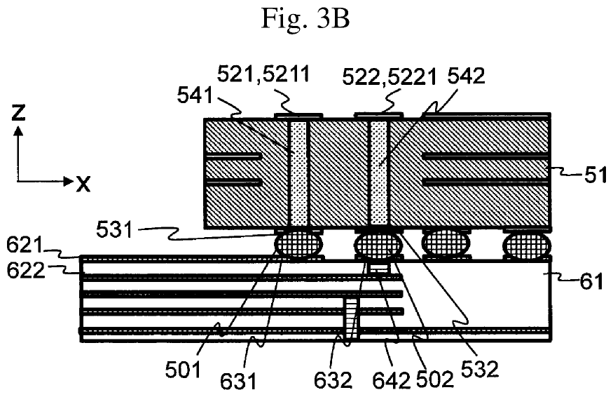

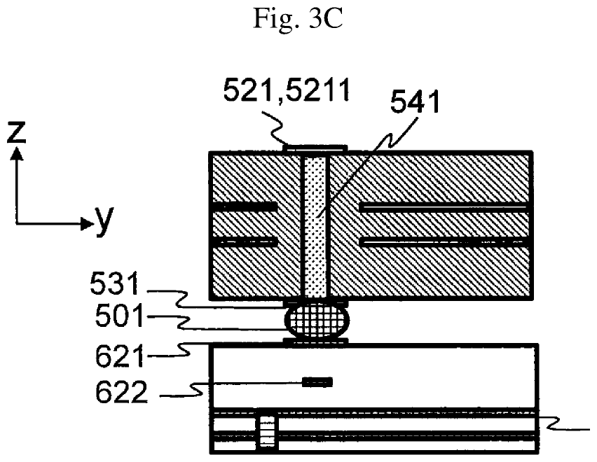

Next, a signal connection structure according to a third embodiment of the present disclosure will be described with reference to FIGS. 3A to 3C. A signal connection 50 according to the present embodiment has substantially the same configuration as the signal connection structure 10 according to the first embodiment, and achieves a similar effect. The signal connection structure 50 differs from the signal connection structure 10 in that the signal connection structure 50 includes one of the conductors forming the broadside strip wiring structure on the top surface of the wiring substrate.

### Configuration of Signal Connection Structure

FIGS. 3A, 3B, and 3C are a top view of the signal connection structure 50 according to the present embodiment, a cross-sectional view taken along line IIIB-IIIB′ in the top view, and a cross-sectional view taken along line IIIC-IIIC′ in the top view, respectively.

The signal connection structure 50 includes a package substrate (dielectric substrate) 51 above a board (wiring substrate) 61. The dielectric substrate 51 has a configuration similar to that of the dielectric substrate 11 in the first embodiment.

In the wiring substrate 61, a signal conductor 621 arranged on the top surface is connected to a connection portion 631 on the top surface. Furthermore, a via 642 is connected to a connection portion 632 on the top surface, and a signal conductor 622 is connected to the via 642. Here, the signal conductor 621 and the signal conductor 622 form a broadside strip wiring structure.

In such a configuration, the surface (the top surface) of the conductor 621 located on the top surface is covered with an air layer, and thus, an asymmetric electromagnetic field mode is obtained. Thus, the conductor 621 is set to be wider than the conductor 622, so that the characteristic impedance can be adjusted to a predetermined value, for example, the differential impedance can be adjusted to 100Ω.

Furthermore, the length of the vias connected to the signal conductors in the wiring substrate can be shortened, and characteristics can be obtained in a wider band.

Thus, with the signal connection structure according to the present embodiment, it is possible to arrange a plurality of differential pairs at high density and obtain high resistance against crosstalk in a wider band.

### Fourth Embodiment

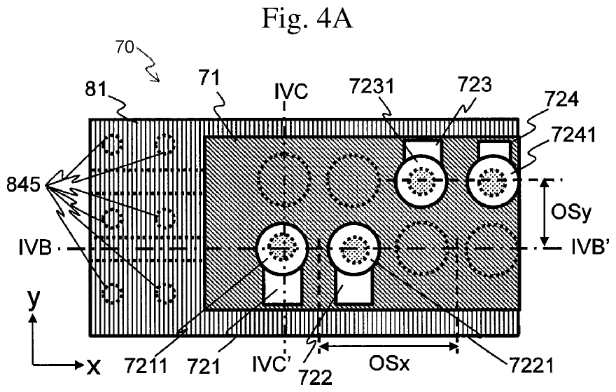

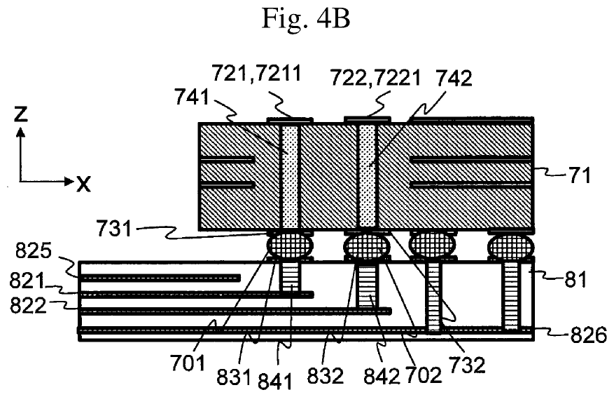

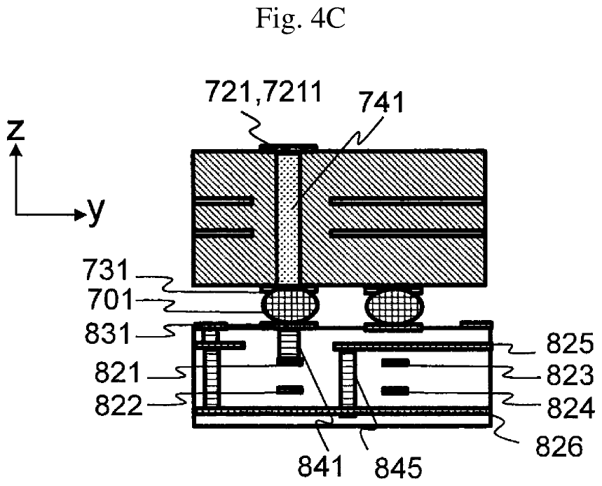

Next, a signal connection structure according to a fourth embodiment of the present disclosure will be described with reference to FIGS. 4A to 4C. A signal connection structure 70 according to the present embodiment has substantially the same configuration as the signal connection structure 10 according to the first embodiment, and achieves a similar effect. The signal connection structure 70 differs from the signal connection structure 10 in that the signal connection structure 70 includes a via connected to the ground between vias of differential signal lines (hereinafter, referred to as “ground via”).

### Configuration of Signal Connection Structure

FIGS. 4A, 4B, and 4C are a top view of the signal connection structure 70 according to the present embodiment, a cross-sectional view taken along line IVB-IVB′ in the top view, and a cross-sectional view taken along line IVC-IVC′ in the top view, respectively.

The signal connection structure 70 includes ground vias 845 between vias of differential signal lines (vias 841 and 842) in a wiring substrate 81.

According to such a configuration, it is possible to suppress coupling of electromagnetic fields between channels, and obtain higher resistance characteristics against crosstalk.

Furthermore, in the present embodiment, an example has been described in which ground vias are provided. However, the embodiment is not limited thereto. A ground pattern arranged in the vicinity of a signal wiring in the same layer as a layer where the signal wiring is arranged may be connected by a ground via.

As described above, with the signal connection structure according to the present embodiment, a plurality of differential pairs can be arranged at high density and coupling of electromagnetic fields between channels can be suppressed, and thus, it is possible to obtain higher resistance against crosstalk.

### Fifth Embodiment

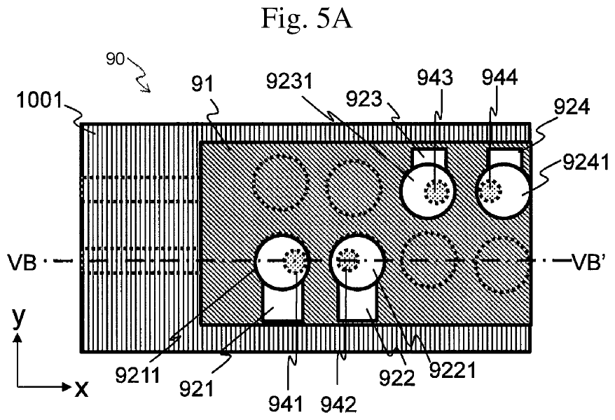

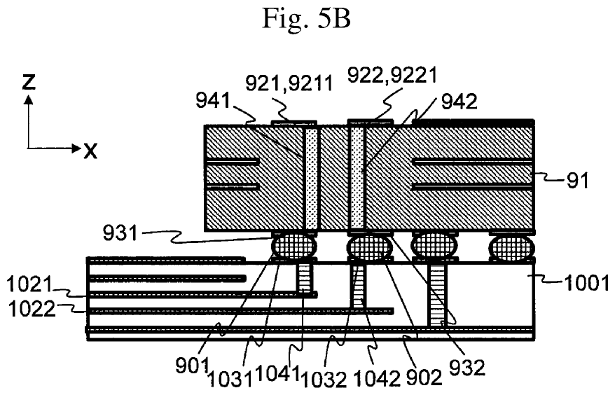

Next, a signal connection structure according to a fifth embodiment of the present disclosure will be described with reference to FIGS. 5A and 5B. A signal connection structure 90 according to the present embodiment has substantially the same configuration as the signal connection structure 10 according to the first embodiment, and achieves a similar effect. In the signal connection structure 90, positions of vias of the connection portions of the differential signal lines are different from those in the signal connection structure 10.

### Configuration of Signal Connection Structure

FIGS. 5A and 5B are a top view of the signal connection structure 90 according to the present embodiment and a cross-sectional view taken along line VB-VB′ in the top view, respectively.

The signal connection structure 90 includes a signal conductor 921 on a top surface of a dielectric substrate 91 and a connection portion 9211 connected to the signal conductor 921. The connection portion 9211 is connected to a via 941 inside the dielectric substrate 91, and the via 941 is connected to a connection portion 931 on a bottom surface of the dielectric substrate 91.

A connection portion 1031 on a top surface of a wiring substrate 1001 is connected to the connection portion 931 on the bottom surface of the dielectric substrate 91 via a signal conductor 901. Furthermore, the connection portion 1031 is connected to a via 1041, and the via 1041 is connected to a signal conductor 1021.

On the other hand, a signal conductor 922 on the top surface of the dielectric substrate 91 is connected to a connection portion 9221, the connection portion 9221 is connected to a via 942 inside the dielectric substrate 91, and the via 942 is connected to a connection portion 932 on the bottom surface of the dielectric substrate 91.

A connection portion 1032 on the top surface of the wiring substrate 1001 is connected to the connection portion 932 on the bottom surface of the dielectric substrate 91 via a signal conductor 902. Furthermore, the connection portion 1032 is connected to a via 1042, and the via 1042 is connected to a signal conductor 1022.

Here, the signal path from the signal conductor 921 to the signal conductor 1021 and the signal path from the signal conductors 922 to the signal conductor 1022 form a differential pair.

In the signal connection structure 90, the via 941 and the via 1041 are arranged closer to the vias 942 and 1042 than the centers of the connection portions 9211, 931, and 1031, in the range of the connection portions 9211, 931, and 1031.

The via 942 and the via 1042 are arranged closer to the vias 941 and 1041 than the centers of the connection portions 9221, 932, and 1032, in the range of the connection portions 9221, 932, and 1032.

That is, the distance between the central axis of the via 941 in the vertical direction (z-direction) and the central axis of the via 942 in the z-direction is shorter than the distance between the center of the connection portion 9211 and the center of the connection portion 9221, or the distance between the center of the connection portion 931 and the center of the connection portion 932.

Furthermore, the distance between the central axis of the via 1041 in the z-direction and the central axis of the via 1042 in the z-direction is shorter than the distance between the center of the connection portion 1031 and the center of the connection portion 1032.

According to this configuration, the electromagnetic fields between the vias in the dielectric substrate 91 and the wiring substrate 1001 can be coupled more strongly, and high resistance against crosstalk can be obtained.

As described above, with the signal connection structure according to the present embodiment, a plurality of differential pairs can be arranged at high density and coupling of electromagnetic fields between vias is strengthened, and thus, it is possible to obtain higher resistance against crosstalk.

### Sixth Embodiment

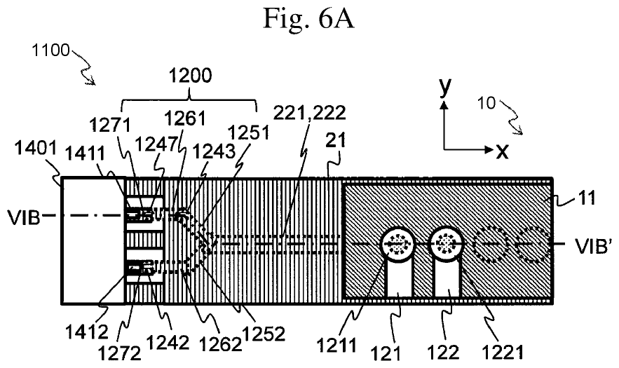

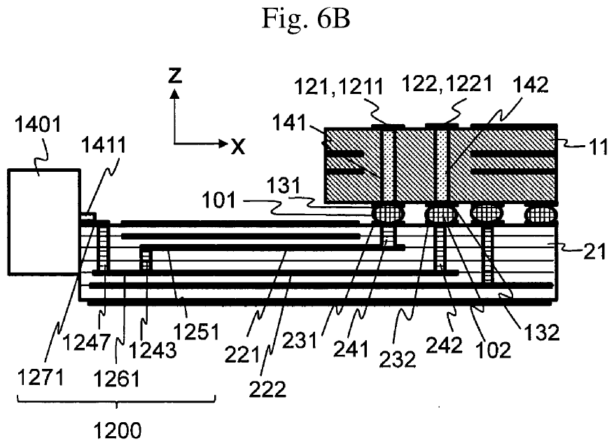

Next, a signal connection structure according to a sixth embodiment of the present disclosure will be described with reference to FIGS. 6A and 6B.

### Configuration of Signal Connection Structure

A signal connection structure 1100 according to a sixth embodiment includes the signal connection structure 10 according to the first embodiment, a coaxial connector 1401, and a structure (hereinafter referred to as “connector connection structure”) 1200 for connecting the signal connection structure 10 and the coaxial connector 1401.

Specifically, the connection portion 1211, the via 141, the connection portion 131, the conductor 101, the connection portion 231, and the via 241 are connected in this order to the signal conductor 121 on the top surface of the dielectric substrate 11, and the via 241 is connected to the signal conductor 221 of the wiring substrate 21.

Furthermore, a connection pattern 1251 is connected to the signal conductor 221, a via 1243 is connected to the connection pattern 1251, the via 1243 is connected to a connection pattern 1261 arranged in the same lower layer as the signal conductor 222, and is connected to a connection pattern 1271 on the top surface of the wiring substrate 21 through a via 1247, and the connection pattern 1271 connects to a pin 1411 of the coaxial connector 1401.

According to such a configuration, a positive phase signal input from the signal conductor 121 on the top surface of the dielectric substrate 11 passes through the connection portion 1211, the via 141, the connection portion 131, the conductor 101, the connection portion 231, and the via 241 in this order, and is conveyed to the signal conductor 221 of the wiring substrate 21.

Subsequently, the positive phase signal passes through the connection pattern 1251, the via 1243, the connection pattern 1261, the via 1247, and the connection pattern 1271, and is conveyed to the pin 1411 of the coaxial connector 1401.

On the other hand, the connection portion 1221, the via 142, the connection portion 132, the conductor 102, the connection portion 232, and the via 242 are connected in this order to the signal conductor 122 on the top surface of the dielectric substrate 11, and the via 242 is connected to the signal conductor 222 of the wiring substrate 21.

Furthermore, a connection pattern 1252, a connection pattern 1262, a via 1242, and a connection pattern 1272 are connected in this order to the signal conductor 222, and the connection pattern 1272 is connected to a pin 1412 of the coaxial connector 1401.

According to such a configuration, a negative phase signal input from the signal conductor 122 on the top surface of the dielectric substrate 11 passes through the connection portion 1221, the via 142, the connection portion 132, the conductor 102, the connection portion 232, and the via 242 in this order, and is conveyed to the signal conductor 222 of the wiring substrate 21. Subsequently, the negative phase signal passes through the connection pattern 1252, the connection pattern 1262, the via 1242, the connection pattern 1272, and is conveyed to the pin 1412 of the coaxial connector 1401.

Here, the interval between the center of the connection portion 1211 and the center of the connection portion 1221, that is, the interval between the via 141 and the via 142 and the like is about 0.5 mm. Furthermore, the signal conductor 221 and the signal conductor 222 have a width of 60 to 70 μm and a length of about 20 mm, and thus, have substantially the same length. However, the signal conductor 222 is longer by the length of the interval between the center of the connection portion 1211 and the center of the connection portion 1221.

Furthermore, the lengths of the connection patterns 1251 and 1261 and the connection patterns 1252 and 1262 each are about 1 mm. The interval between the pin 1411 and the pin 1412 of the coaxial connector 1401 is about 3 mm.

The via 241 and the via 1243 have a cross-sectional diameter of about 80 μmφ and a length of about 200 μm, and have substantially the same shape. Furthermore, the vias 242 and 1247 have a cross-sectional diameter of about 80 μmφ and a length of about 400 μm, and have substantially the same shape.

Thus, the signal conductor 221 and the signal conductor 222 are arranged one above the other in the wiring substrate 21 to form a differential signal pair, and form a broadside strip line in which electromagnetic fields are coupled in the up-down direction.

The signal conductor 221 is connected to the same lower layer as the signal conductor 222 via the via 1243, and thus, the signal conductor 221 and the signal conductor 222 form, in the same lower layer as the signal conductor 222, a broadside strip line in which electromagnetic fields are coupled in a horizontal direction (y-direction).

In addition, according to this configuration, it is possible to eliminate the skew difference in the differential pair due to the difference in the length of the vias in the wiring substrate 21, and good frequency characteristics can be obtained.

Here, the skew difference in the differential pair occurs due to the difference between the lengths of the signal conductor 221 and the signal conductor 222 corresponding to the interval between the center of the connection portion 1211 and the center of the connection portion 1221. However, the skew difference can be reduced by adjusting the difference in length between the connection patterns 1251 and 1261 and the connection patterns 1252 and 1262.

As described above, with the signal connection structure according to the present embodiment, when connection to an element or component outside the wiring substrate is made, for example, when a signal is transmitted with connection made to a coaxial connector, it is possible to connect a coaxial connector structure, without causing a skew difference in the differential channel.

Furthermore, the signal connection structure according to the present embodiment includes the signal connection structure 10 according to the first embodiment, and thus, an effect similar to the first embodiment is of course achieved.

In an embodiment of the present disclosure, an example has been described in which adjacent connection portions in a differential pair are arranged at an interval of 0.5 mm. However, the present disclosure is not limited thereto, the interval may be about several hundred μm, and any interval may be used as long as the adjacent connection portions may be arranged efficiently and the differential signal can be well transmitted.

In an embodiment of the present disclosure, an example has been described in which adjacent differential pairs are arranged at an interval (OSx) of 1 mm in the x-direction and an interval (OSy) of 1 mm in the y-direction. However, the present disclosure is not limited thereto, the interval may be several mm, and any interval may be used as long as the adjacent differential pairs may be arranged efficiently, high resistance against crosstalk is achieved, and the differential signal can be well transmitted.

In an embodiment of the present disclosure, an example has been described in which a positive phase signal is input from the signal conductor 121 on the top surface of the dielectric substrate 11 and a negative phase signal is input from the signal conductor 122 on the top surface of the dielectric substrate 11. However, the negative phase signal may be input from the signal conductor 121 on the top surface of the dielectric substrate 11 and the positive phase signal may be input from the signal conductor 122 on the top surface of the dielectric substrate 11.

In an embodiment of the present disclosure, an example has been described in which a signal connection structure includes one to three differential pairs. However, this is an example for describing a part of a signal connection structure, and even when the signal connection structure includes a plurality of differential pairs, a similar effect is achieved.

In an embodiment of the present disclosure, an example of the structure, dimension, material, and the like of each configuration unit in the configuration, manufacturing method, and the like of the signal connection structure has been described. However, the present disclosure is not limited thereto. The structure, dimension, material, and the like are only required to exhibit functions and produce effects of the signal connection structure.

### INDUSTRIAL APPLICABILITY

The present disclosure can be applied to wiring substrates, mounted substrates, and the like in high-frequency devices, and to semiconductor apparatuses.

1-8. (canceled)

9. A wiring substrate comprising:
a plurality of differential pairs;
wherein each of the plurality of differential pairs comprises a first signal conductor, a first connection portion connected to the first signal conductor by a first via, a second signal conductor, and a second connection portion connected to the second signal conductor by a second via;
wherein the first signal conductor and the second signal conductor are arranged on different planes parallel to a bottom surface of the wiring substrate and overlap in a vertical direction;
wherein the first connection portion and the second connection portion are arranged on a top surface of the wiring substrate at a first predetermined interval in a signal transmission direction; and
wherein adjacent differential pairs among the plurality of differential pairs are arranged at a second predetermined interval in the signal transmission direction and at a third predetermined interval in a direction perpendicular to the signal transmission direction.

10. The wiring substrate according to claim 9, further comprising a ground conductor surrounding the first signal conductor and the second signal conductor.

11. The wiring substrate according to claim 9, wherein the first signal conductor is arranged on the top surface of the wiring substrate.

12. The wiring substrate according to claim 9, further comprising a third via between the first via and the second via, wherein the third via is connected to a ground.

13. The wiring substrate according to claim 9, wherein a distance between the first via and the second via is shorter than a distance between a center of the first connection portion and a center of the second connection portion.

14. The wiring substrate according to claim 9, wherein the first signal conductor and the second signal conductor form a broadside strip wiring structure.

15. The wiring substrate according to claim 9, further comprising:
a ground conductor surrounding the first signal conductor and the second signal conductor; and
a third via between the first via and the second via, wherein the third via is connected to a ground.

16. The wiring substrate according to claim 15, wherein the first signal conductor is arranged on the top surface of the wiring substrate.

17. The wiring substrate according to claim 16, wherein a distance between the first via and the second via is shorter than a distance between a center of the first connection portion and a center of the second connection portion.

18. A signal connection structure comprising:
a wiring substrate comprising:
a plurality of differential pairs;
wherein each of the plurality of differential pairs comprises a first signal conductor, a first connection portion connected to the first signal conductor by a first via, a second signal conductor, and a second connection portion connected to the second signal conductor by a second via;
wherein the first signal conductor and the second signal conductor are arranged on different planes parallel to a bottom surface of the wiring substrate and overlap in a vertical direction;
wherein the first connection portion and the second connection portion are arranged on a top surface of the wiring substrate at a first predetermined interval in a signal transmission direction; and
wherein adjacent differential pairs among the plurality of differential pairs are arranged at a second predetermined interval in the signal transmission direction and at a third predetermined interval in a direction perpendicular to the signal transmission direction;
a dielectric substrate above the wiring substrate;
connection portions on a bottom surface of the dielectric substrate; and
connection portions located on a top surface of the dielectric substrate and connected by vias penetrating the dielectric substrate, wherein the connection portions on the bottom surface of the dielectric substrate and the connection portions on the top surface of the wiring substrate are connected by conductors.

19. The signal connection structure according to claim 18, further comprising a coaxial connector.

20. The signal connection structure according to claim 19, wherein:
the first signal conductor is connected by a third via to a first connection pattern arranged in a layer identical to a layer where the second signal conductor is arranged;
the first connection pattern is connected by a fourth via to a second connection pattern arranged on the top surface of the wiring substrate; and
the second connection pattern is connected to a first pin of the coaxial connector.

21. The signal connection structure according to claim 20, wherein:
the second signal conductor is connected by a fifth via to a third connection pattern arranged on the top surface of the wiring substrate; and
the third connection pattern is connected to a second pin of the coaxial connector.

22. The signal connection structure according to claim 18, further comprising a ground conductor surrounding the first signal conductor and the second signal conductor.

23. The signal connection structure according to claim 18, wherein the first signal conductor is arranged on the top surface of the wiring substrate.

24. The signal connection structure according to claim 18, further comprising a third via between the first via and the second via, wherein the third via is connected to a ground.

25. The signal connection structure according to claim 18, wherein a distance between the first via and the second via is shorter than a distance between a center of the first connection portion and a center of the second connection portion.

26. The signal connection structure according to claim v, wherein the first signal conductor and the second signal conductor form a broadside strip wiring structure.
